(19) United States
(12) Patent Application Publication
(10) Pub. No.: US 2006/0185591 A1
(43) Pub. Date: Aug. 24, 2006

(54) High temperature chemical vapor deposition apparatus

(75) Inventors: Lakshmipathy Muralidharan, Tamil Nadu (IN); Demetrius Sarigiannis, Medina, OH (US); Patricia Hubbard, Olmsted Falls, OH (US); Marc Schaepkens, Medina, OH (US); Atul Pant, Bangalore (IN)

Correspondence Address: GEAM - QUARTZ;IP LEGAL, ONE PLASTICS AVENUE, PITTSFIELD, MA, 01201-3697, US

(73) Assignee: General Electric Company

(21) Appl. No.: 11/344,854

(22) Filed: Feb. 1, 2006

Related U.S. Application Data
(63) Continuation-in-part of application No. 11/291,558, filed on Dec. 1, 2005.
(60) Provisional application No. 60/654,654, filed on Feb. 18, 2005.
(60) Provisional application No. 60/752,505, filed on Dec. 21, 2005.

(51) Int. Cl. C23C 16/00

(52) U.S. Cl. 118/715; 427/248.1

(57) ABSTRACT

Embodiments for an apparatus and method for depositing one or more layers onto a substrate or a freestanding shape inside a reaction chamber operating at a temperature of at least 700° C. and 100 torr are provided. The apparatus is provided with a feeding system having injection means for differential pre-reactions and/or pre-treating of a plurality of gases or gas mixtures, tailoring the distribution of a plurality of gas-phase species, yielding a deposit that is substantially uniform in thickness and chemical composition along the substrate surface. In one embodiment, the apparatus further comprises a sacrificial substrate that further helps achieving thickness and chemical uniformity on the substrate, by imitating a continuous surface to deposit on and thus preventing any disturbances in the flow pattern especially towards the edge of the substrate.

### CROSS REFERENCE TO RELATED APPLICATION

This application claims priority to U.S. Provisional Patent Application No. 60/654654 with a filing date of Feb. 18, 2005 and U.S. Provisional Patent Application No. 60/752505 with a filing date of Dec. 21, 2005, which patent applications are fully incorporated herein by reference. This application is also a CIP of and claims priority to U.S. patent application Ser. No. 11/291558, with a filing date of Dec. 1, 2005.

### FIELD OF INVENTION

The present invention relates to a high temperature CVD apparatus.

### BACKGROUND OF THE INVENTION

Chemical vapor deposition (“CVD”) is a widely used production process for the application of a coating to a substrate, as well as for the fabrication of freestanding shapes. In a CVD process, the formation of the coating or the freestanding shape occurs as a result of chemical reactions between volatile reactants that are injected into a reactor containing a heated substrate and operating at sub-atmospheric pressure. The substrate could be part of the final coated product, or could be sacrificial in the case of fabrication of freestanding shapes. The chemical reactions that are responsible for the formation of the coating or freestanding products are thermally activated, taking place either in the gas-phase, on the substrate surface, or both. The reaction is very much dependent on a number of variables, including reactant chemistries, reactant flow rates, reactor pressure, substrate temperature, reactor geometries, and other hardware and process parameters.

CVD reactors, particularly low temperature CVD reactor configurations, have been used for applications such as thin film depositions for semiconductor device fabrication, or for the coating deposition of various reactant chemistries. High temperature CVD reactor configurations have been used to deposit coatings on graphite substrates for use in heater applications; or to deposit freestanding shapes like pyrolytic boron nitride crucibles for III-V semiconductor crystal growth. In prior art reactor configurations when the substrate is heated to relatively low temperatures, i.e. less than 1000° C., most chemistries will form a deposit on the substrate through a reaction limited deposition mechanism, where the chemical reactions mainly take place at the substrate surface, as is illustrated in FIG. 1. The resulting deposits that are formed at relatively low temperatures, i.e., in the reaction-limited regime, may be highly uniform in thickness and chemistry, but their deposition rates are typically relatively low, dependent on operating pressure and flows.

In the prior art reactor configurations for relatively high substrate temperatures, i.e. >1000° C., most chemistries will form a deposit 4 on the substrate 5 through a mass transport limited mechanism as illustrated in FIG. 2. In the mass transport limited regime, or near the transition between the mass transport limited and reaction limited regime, the chemical reactions can take place at the surface but also in the gas-phase.

In an example of a high-T CVD process such as the deposition of pyrolytic boron nitride (PBN), it is well accepted that BCl₃ and NH₃ reactants form intermediate species, including but not limited to Cl₂BNH₂. The intermediate species are subsequently transported to the substrate surface to go through additional chemical reactions, forming PBN deposits and reaction by-products, including but not limited to HCl. In addition, BCl3 and NH3 can diffuse to the surface and directly deposit PBN. An example of a prior art high T CVD reactor configuration is shown in FIG. 3, for a chamber 11 to deposit coatings or forming freestanding shapes. The chamber 11 contains an assembly of resistive heating elements 55 and a flat substrate 5. Reaction gases 1-3 enter and exhaust the gas chamber through exhaust lines 600. The deposits 4 are formed at high temperature, i.e. near the transition to or in the mass transport limited regime, with relatively high growth rates of >0.5 micron/min, dependent on operating pressure and flows. However, the deposited material in the reactor chamber of the prior art typically suffers from non-uniformities in thickness and chemistry, i.e. the deposited thickness and chemistry uniformities, expressed as the ratio of standard deviation to average, are typically larger than 10%.

The chemical non-uniformity issue is especially important when mixtures of gases are used for the formation of materials with relatively complex chemistries, i.e., doped materials. If one gas or gas mixture reacts slower to form deposited film than the other gas or gas mixtures, then it is likely that the deposits formed from the first gas or gas mixture have a different deposition rate profile than the deposit formed from the other gas or gas mixture. The chemical composition of the composite material may therefore vary significantly across the substrate surface, for undesired varying coating thicknesses.

There is a need for CVD apparatus configurations that provide both high uniformity and high growth rates for applications requiring both criteria, particularly for the formation of certain chemical compositions such as pBN, aluminum nitride, doped pBN or doped AlN, etc., which can only be formed at high temperatures with the desired properties. There is also a need for high temperature CVD apparatus configurations that operate near or in the mass transport limited regime to deposit materials with a highly controllable thickness and chemistry profile.

The present invention relates to improved high temperature chemical vapor deposition apparatus configurations for the fabrication of coated and freestanding products requiring a highly controllable thickness and chemistry profile, with high uniformity and at high growth rates.

### SUMMARY OF THE INVENTION

In one aspect, the invention relates to a high temperature chemical vapor deposition (CVD) system comprising a vacuum reaction chamber maintained at a pressure of less than 100 torr, housing a substrate or a free-standing object to be coated; a reactant feed supply system for providing at least two reactant feeds to the chamber; an outlet unit from the reaction chamber; heating means for maintaining the substrate at a temperature of at least 700° C.; and a feeding system having a plurality of injection means for a plurality of gases or gas mixtures, wherein the plurality of injection means are spatially spaced apart.

In another embodiment, the apparatus further comprises rotating means for rotating the substrate to be coated, for a coating deposit that is substantially uniform in thickness and chemical composition along the substrate surface.

In another embodiment, the apparatus further comprises a sacrificial substrate, providing a continuous surface adjacent to and surround the substrate surface to be coated.

In another embodiment, the feeding system having injection means comprising a plurality of injection pipes having a plurality of distribution holes along the length of the injection pipes. In one embodiment, the holes are angled both above and below from the mid-plane of the pipes, bisecting the substrate along its thickness for depositing a uniform coating onto the substrate. In yet another embodiment, the feeding system having injection means comprising injection pipes containing alternating set of feed holes so as to provide uniform supply of reactant feeds over the substrate.

In one embodiment, the apparatus comprises a vacuum vessel; a substrate treatment zone; at least one heated substrate; a feeding system comprising a plurality of injection points for providing reactant feeds, the injection points positioned at different distances from said substrate and at least one gas exhaust zone for drawing the reactant feeds over the substrate surface to be coated.

In yet another embodiment for an apparatus for the deposition of, amongst other materials, doped coating layers on a substrate, the apparatus further comprises a divider-plate on one or both sides or each substrate to be coated for maximizing the precursor flow between the substrates, hence maximizing the dopant deposition on the inner side of the substrate.

In another embodiment, the invention relates to an apparatus for the deposition of, amongst other materials, carbon-doped pyrolytic boron nitride on a substrate, wherein the reactant feeds, CH₄ optionally in a carrier such as N₂, BCl₃ and NH₃, are differentially located for the dopant feed CH₄ to have a longer residence time before reaching the substrate, thus to be pre-treated and/or undergoing a decomposition reaction to form a methane derived gas phase intermediates, forming a substantially uniform thickness and chemical composition across the substrate with similar BN deposition and C deposition profiles.

### BRIEF DESCRIPTION OF THE DRAWINGS

FIG. 1 is a schematic diagram showing the CVD mechanism in the reaction limited (lower temperature) regime.

FIG. 2 is a schematic diagram showing the chemical vapor deposition (CVD) mechanism in the mass transport limited (high temperature) regime.

FIG. 3 is a schematic sectional view of a prior art CVD deposition apparatus.

FIG. 4 is a perspective view of the first embodiment of the apparatus of the invention for an injector feed system having differential injection systems of multiple feed gases.

FIG. 5(A) is a perspective view of the 2^{nd} embodiment of the apparatus of the invention, further provided with a sacrificial substrate template. FIG. 5(B) is a sectional view of the apparatus of FIG. 5(A) along line A-A′.

FIGS. 6A, 6B, 6D, and 6D are schematic views of different embodiments of the injector feed systems of the invention.

FIG. 7 is a graph illustrating the three-dimensional computational fluid dynamics (CFD) calculations on the embodiment of the invention as illustrated in FIGS. 5A and 5B, comparing the pBN deposition rates (in kg/m².s) profiles (on the substrate) as various apparatus parameters are changed.

FIG. 8 is a graph illustrating three-dimensional CFD calculations comparing the carbon deposition profiles (in kg/m².s) for the cases in FIG. 7.

FIG. 9 is a graph comparing the three-dimensional CFD calculations comparing the film composition (carbon percentage) profiles of the cases illustrated in FIG. 7.

FIG. 10 is a graph illustrating the dependence of the electrical resistance characteristics of carbon doped pyrolitic boron nitride (CpBN) film on the carbon percentage.

FIG. 11 is a graph illustrates the sensitivity of resistance of the CPBN film on a substrate to the flow rate of CH4 from the first injector system.

FIG. 12 is a graph illustrating the resistance non-uniformity (measured as ratio of maximum to minimum resistance on the substrate) variation with the CH4 flow rate.

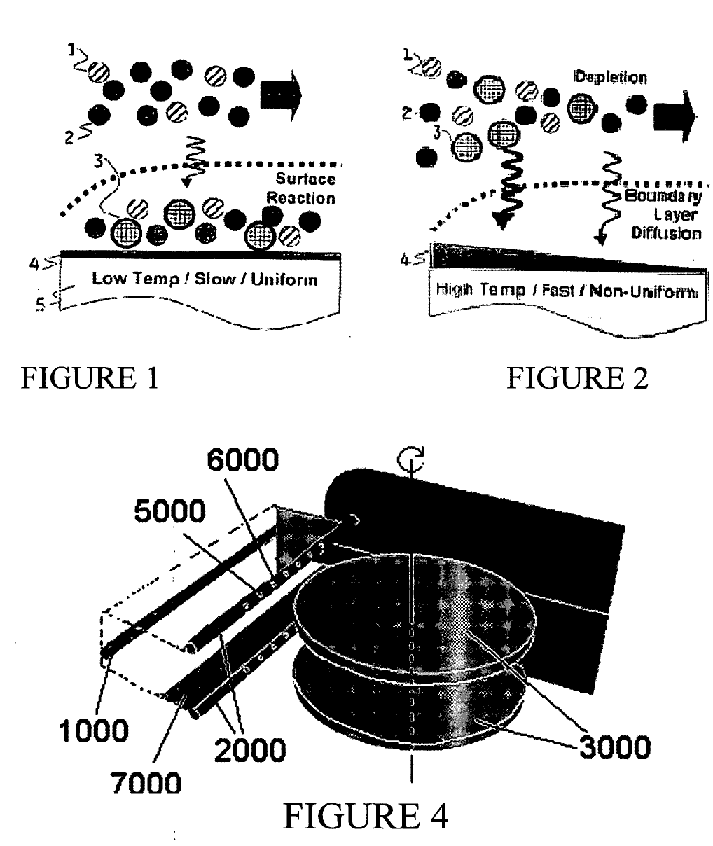

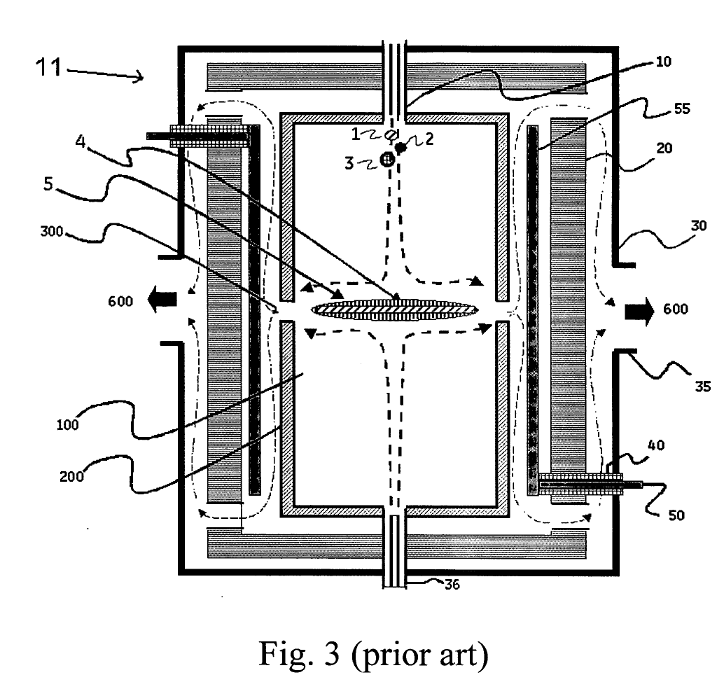

### DETAILED DESCRIPTION OF THE INVENTION

The terms “a” and “an” herein do not denote a limitation of quantity, but rather denote the presence of at least one of the referenced item. All ranges disclosed herein are inclusive and combinable. Furthermore, all ranges disclosed herein are inclusive of the endpoints and are independently combinable. Also, as used in the specification and in the claims, the term “comprising” may include the embodiments “consisting of” and “consisting essentially of.”

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases. In at least some instances, the approximating language may correspond to the precision of an instrument for measuring the value.

As used herein, CVD apparatus may be used interchangeably with CVD chamber, reaction chamber, or CVD system, referring to a system configured to process large areas substrates via processes such as CVD, Metal Organic CVD (MOCVD), plasma enhanced CVD (PECVD), or organic vapor phase deposition (OVPD) such as condensation coating, at high temperatures of at least 700° C., and in some embodiments, over 1000° C. The apparatus of the invention may have utility in other system configurations such as etch systems, and any other system in which distributing gas within a high temperature process chamber is desired.

As used herein, “substrate” refers to an article to be coated in the CVD apparatus of the invention. The substrate may refer to a sacrificial mandrel (a mold or shape to be discarded after the CVD is complete, and only the hardened shaped coating is kept), a heater, a disk, etc., to be coated at a high temperature of at least 700° C. in one embodiment, and at least 1000° C. in another embodiment.

As used herein, “pre-reacting” or “pre-react” means the reactants are heated and/or react with one another in the gas phase, forming at least a gaseous precursor or reaction intermediate. As used herein, “pre-reacting phase” or “pre-reaction phase” means the phase or period in time wherein reactants are heated and/or react with one another in the gas phase, forming at least a gaseous precursor. As used herein, “pre-reacting zone” or “pre-reaction zone” means a volume space, a zone, space, or location within the chamber wherein the reactants react with one another in the gas phase, forming gaseous precursors.

As used herein, “pre-heat” may be used interchangeably with “pre-treat,” “pre-heated” may be used interchangeably with “pre-treated,” and “pre-heating” may be used interchangeably with “pre-treating,” generally referring to the action or the process of changing the properties of the reactants, by heating them and/or causing them to pre-react forming at least a gaseous precursor or reaction intermediate. For example in one embodiment, a localized plasma or other sources of energy may be used for a plasma treatment, UV treatment, or microwave treatment to alter the properties of the gas reactants prior to reaching the substrate, turning them into precursors for deposition onto the substrate.

As used herein, “pre-treating zone” or “pre-heating zone” means a volume space, a zone, space, or location within the chamber wherein the reactants are pre-heated and/or pre-treated, forming gaseous precursors.

As used herein, “deposition phase” refers to the phase or period in time wherein reactants and/or the gaseous precursors react with one another forming a coating onto a substrate. “Deposition zone” refers to a volume space, a zone, space, or location where the substrate is coated or where the reacted precursor is deposited onto the substrate. It should be noted that the deposition zone and the pre-reaction zone may not be necessarily and entirely spatially apart and there may be some overlapping in volume or space between the pre-reaction zone and the deposition zone.

As used herein, the term “jets,” “injectors,” or “nozzles” may be used interchangeably and denoting either the plural or singular form. Also as used herein, the term “precursor” may be used interchangeably with “reaction intermediate” and denoting either the plural or singular form.

The invention relates to high temperature CVD (“thermal CVD”) apparatuses, and a process for producing one more layers on at least one substrate disposed in the reaction chamber of the thermal CVD apparatuses, using at least one of a liquid, a solid, or a reaction gas as a starting material or a precursor, operating at a temperature of at least 700° C. and a pressure of <100 torr. In one embodiment, the thermal CVD apparatus is for CVD depositions at >1000° C. In another embodiment, the thermal CVD apparatus is operated at a pressure <10 torr. It should be noted that the thermal CVD apparatus of the invention could be used for coating substrates, as well as for the fabrication of freestanding shapes.

Feed Materials: The feed materials comprise a plurality of reactants. In one embodiment, the reactant feed material is an organic or a non-organic compound which is capable of reacting, including dissociation and ionizing reactions, to form a precursor or reaction product which is capable of depositing a coating on the substrate. The reactant may be fed as a liquid, a gas or, partially, as a finely divided solid. When fed as a gas, it may be entrained in a carrier gas. The carrier gas can be inert or it can also function as a fuel. In one embodiment, the reactant material is in the form of droplets, fed to the downstream, temperature-controlled chamber, where they evaporate. In another embodiment, the starting material is in the form of a vapor or a liquid, fed to the chamber with the assistance of a carrier gas prior to being introduced to the chamber. In yet another embodiment, the reactant material is introduced directly to the chamber through a gas inlet mean.

In one embodiment for the deposition of AlN on a substrate, the following reaction takes place: AlCl₃+NH₃→AlN+3HCl. In one embodiment, the starting feed comprises the feeding of NH₃, N2, and H2. In a second embodiment, the starting feed further comprises N₂O gas, dry air and water vapor (H₂O) for covering AlN graded layers with Al₂O₃.

In a second embodiment for the formation of a doped AlN coating on a substrate, such as the doping of AlN with Se, the feed may include a plurality of reactants as well as carrier gas, e.g., nitrogen, ammonia NH₃, aluminum chloride (AlCl₃), and any of H₂ S, Se(CH₃)₂, H₂ Se for the dopants.

In a third embodiment for the formation of a pyrolytic boron nitride coating (BCl₃+NH3→BN+3HCl) doped with carbon and/or oxygen, the feed may include a plurality of reactants including: C and O dopants CH₄, O₂, N₂O, air, CO, CO₂ or mixtures of O containing ethane, propane, methanol, and ethanol, introduced by injection; and reactants BCl₃ and NH₃.

Deposited Coating: The deposited material which can be applied by the apparatus and process of the invention can be any inorganic or organic material. In one embodiment, the deposited coating comprises at least one of an oxide, nitride, oxynitride of elements selected from a group consisting of Al, B, Si, Ga, refractory hard metals, transition metals, and combinations thereof. In another embodiment, the deposited coating further comprises at least a dopant selected from the group of silicon, carbon, and oxygen, and mixtures thereof.

Examples of inorganic deposited materials include metals, metal oxides, sulfates, phosphates, silica, silicates, phosphides, nitrides, borides and carbonates, carbides, other carbonaceous materials such as diamonds, and mixtures thereof. Organic coatings, such as polymers, can also be deposited from reactive precursors, such as monomers, by those embodiments of the invention which avoid combustion temperatures in the reaction and deposition zones.

In one embodiment, the deposited material is pBN for the formation of pBN coated heaters or freestanding PBN crucibles. In a second example of the embodiment, doped AlN is deposited as coating layers for heater substrates or wafer susceptors.

The coating can be deposited to any desired thickness. In one embodiment, the coating deposit comprises one or more layers on the substrate, for a substantially uniform chemical modification of the substrate. In one embodiment, highly adherent coatings at thicknesses between 10 nanometers and 5 micrometers are formed. In a second embodiment, the coatings have a thickness of 1 to 1000 micrometers.

Substrate to be Coated: The substrates coated by the inventive apparatus/process of the invention can be virtually any high-temperature compatible solid material, including metal, ceramic, glass, etc. In one embodiment, the process of the invention is for the fabrication of carbon doped pyrolitic boron nitride (cPBN) based heaters and chuck used in semiconductor wafer processing equipment. In another embodiment, the process is for the fabrication of freestanding shapes, including but not limited to the fabrication of pyrolitic boron nitride (PBN) vertical gradient freeze (VGF) crucibles or liquid-encapsulated Czochralski (LEC) crucibles, for use in the fabrication of compound semiconductor wafers.

Embodiments of the Apparatus of the Invention: The high temperature CVD apparatus of the invention is provided with means to allow at least one of the reactants to be pre-treated, and/or pre-react forming volatile reaction intermediates in a separate zone, prior to the deposition phase in a deposition zone. This zone can be a pre-treating zone or a pre-reaction zone. In the apparatus of the invention, this zone is spatially apart from the deposition zone, allowing the reactants to have a sufficient residence time for the homogeneous gas-phase conversion of reactants to precursors for deposition (including reaction intermediate species). The apparatus of the invention may also be used with pre-heated/pre-treated species that are ready for deposition in a deposition zone.

The spatial separation of the pre-reaction zone and/or the pre-treating zone from the deposition zone allows the precursors to react in the deposition zone and uniformly distribute the reacted intermediate species on the substrate to be CVD-coated. The size of the zones, and thus the residence time in each zone, may be controlled by varying system variables including but not limited to the chamber pressure, the substrate temperature, the reactant feed rates, the size and shape of the substrate and the size & shape of the exhaust area or areas.

Injector Feed Systems with Differential Spacing: FIG. 4 is a schematic perspective view of the first embodiment of the apparatus of the invention, for a CVD chamber 11 with differential injector feed spacing from the substrate to be coated. The reactor supply system comprises a plurality of injectors 1000 and 2000 being spaced further apart, for the reactants to have sufficient time to pre-react or to be pre-treated prior to the deposition phase and create pre-reaction and deposition zones. The first injector system comprises at least one injector feed pipe 1000 for feeding at least a reactant feed, e.g., CH₄ with or without a carrier gas such as N₂, into the CVD chamber 11. A secondary injector system 2000 with at least one injector pipe, for injecting at least a 2^{nd} reactant feed into the reactor, e.g., BCl₃ and NH₃ as a mixture or in separate feed streams through holes 5000 and 6000 respectively, with and without a carrier gas such as N₂.

As illustrated in FIG. 4, the first injector system 1000 is placed at a distance sufficient further away from the substrate 3000 and the second injector 2000 to enable the pre-heating and/or pre-reaction/pre-treating of the feed reactant in injector 1000 and/or the uniform deposition of reaction intermediates on the substrate.

By “sufficient distance away” herein means a length of a sufficient distance away to allow the substrate to have relatively uniform coating thickness and chemistry on the surface of the substrate, i.e., a thickness difference of less than 10% between two extreme thickness locations in the coating of the substrate (of the same side, either top or bottom side of the substrate). In a second embodiment, the substrate has a thickness difference of less than 7% between two extreme thickness locations in the coating of the substrate. In one embodiment, the coating has a uniform thickness of less than 10% variation expressed as ratio of standard deviation to average of the thicknesses on one side of the substrate.

In one embodiment, the substrate has a relatively uniform chemistry on the surface of the substrate, i.e., a concentration difference in any of the elements in the coating of less than 10% between two extreme locations in the coating of the substrate (of the same side, either top or bottom), expressed as a ratio of standard deviation to average. As used herein, elements in a coating of carbon doped pBN on a substrate means the concentration of Carbon C or the concentration of pBN on the substrate.

In one embodiment, the first injector system 1000 is placed at a position between 1.5 to 20 times the length between the second injector system 2000 and the substrate 3000. In another embodiment, the first injector system 1000 is placed at a position between 3 to 18 times the length between the second injector system 2000 and the substrate 3000. In a third embodiment, at a distance between 5 to 10 times the length between the 2^{nd} injector system 2000 and the substrate 3000.

In one embodiment, the first injector system 1000 is placed at a distance sufficient further away from the second injector 2000 to allow a localized plasma or other sources of energy to be placed in between the first injector system 1000 and the second injector system 2000, e.g., a plasma treatment, UV treatment, or microwave treatment to alter the properties of the gas reactant from injector system 1000 prior to its reaching the reactant gas from the injector system 2000, for further reaction prior to reaching the deposition zone for coating the substrate.

In a second embodiment, the further distance apart from the first injector system 1000 to the deposition substrate 3000 allows for a reactant feed that needs a longer residence time to go through a relatively slow decomposition reaction before reaching the substrate. As illustrated the FIG. 4, reactant feed from injector system 1000 has a longer residence time to be pre-treated and/or substantially pre-react forming intermediate precursor in the pre-reaction zone defined by partition plates or divider plates 7000 (volume extending to the left of the Figure, as defined by dotted line).

In one example for the deposition of C-doped pBN, carbon dopant in the form of CH₄ feed which needs longer residence time to form a methane derived gas phase intermediate is fed through the 1^{st} injector system 1000. Reactants that need lesser residence time, e.g., the BCl₃ and NH₃ reactants for the formation of pBN, are fed to the chamber 11 via the second injector system 2000. The shorter distance between the injector system 2000 and the deposition substrate 3000 allows BCl₃ and NH₃ to go through a relatively fast gas phase reaction forming one or more gas phase intermediates. By the time the feed streams from injector systems 1000 and 2000 reach the substrate 3000, the CH₄-based gas stream and the BCl₃/NH₃ based gas streams will be ready to deposit in a mass transport, depletion limited fashion and yield similar BN deposition and C deposition profiles on the substrate 3000, thus a substantially uniform C-doped pBN composition across the substrate 3000.

In another embodiment for use in depositing pBN crucibles (not shown), a mandrel is placed in place of the substrate 3000. The mandrel can be suspended from the top of a chamber 11 by a plurality of rods as with a substrate. In yet another embodiment (not shown), the substrates 3000 can be suspended from the top of chamber 11 by a plurality of rods, or it may be supported by a support assembly (not shown) connected to the sidewall of the chamber. In yet another embodiment, the support assembly further comprises a stem coupled to a lift system allowing positioning the substrate(s) 3000 at a desired level within the chamber.

In one embodiment of the invention (not shown), the support assembly further comprises rotating mechanism, e.g., turntables rotating around a shaft, allowing the substrates to rotate about an axis which is normal to the surface of the substrates. The rotation further ensures uniformity of the coating thickness, for the reactant feeds through injector systems 1000 and 2000 to uniformly reach all substrate surfaces. In operation, the substrate 3000 may be first rotated at a slow speed, e.g., 1 to 150 rpm until a desired film thickness is obtained, then the speed of rotation of the substrate may be increased and the rotation continues until a uniform coating is obtained. In one embodiment, the rotation speed of the substrate varies in the range of 5-100 rpm.

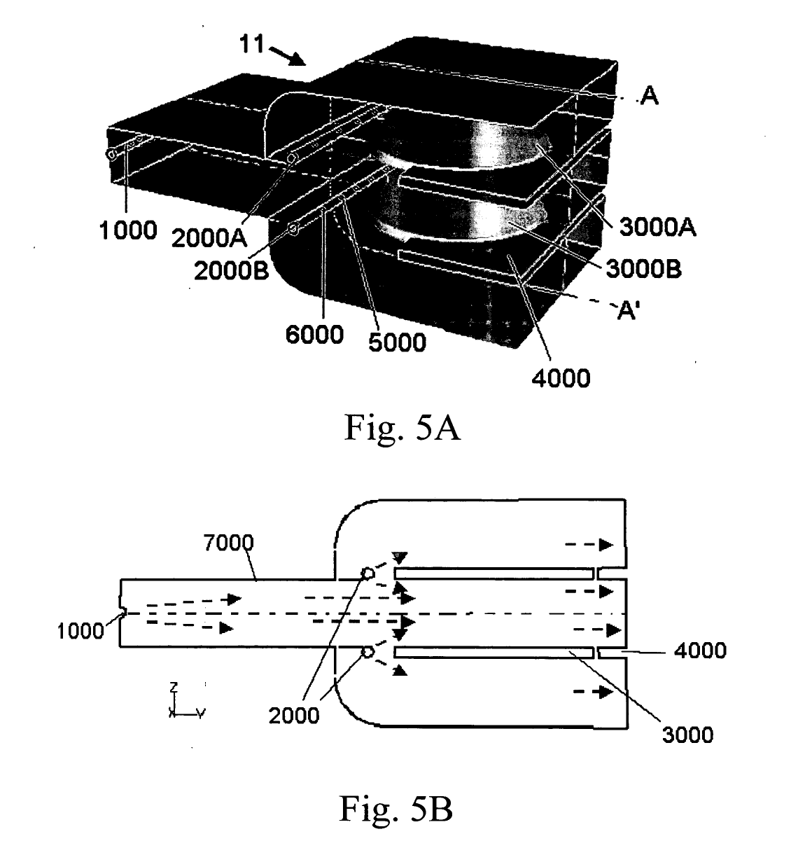

Sacrificial Substrates for Improved Coating Uniformity: In one embodiment of the embodiment as illustrated in FIGS. 5A and 5B, the apparatus is further provided with a sacrificial substrate 4000 for each of the substrate 3000. Applicants have found that the sacrificial substrate 4000 further help achieve thickness and chemical uniformity on the substrate 3000, by imitating a continuous surface to deposit on and thus preventing any disturbances in the flow pattern especially towards the edge of the substrate.

In one embodiment as illustrated in FIGS. 5A and 5B, the sacrificial substrate 4000 is adjacent to a backside of the device substrate 3000. In another embodiment (not shown), the sacrificial substrate 4000 may be compatible in size and shape to the substrate 3000, forming a sacrificial structure adjacent to/surrounding the entire substrate 3000 (as opposed to ½ of the substrate 3000 as illustrated in FIG. 5A). After the completion of the coating process, the sacrificial substrate 4000 may be severed from the substrate and discarded.

Divider Plates: In yet another embodiment as illustrated in FIGS. 5A and 5B, the apparatus further comprises a plurality of divider plates, each position at or about the same level with the substrate, thus maximizing the flow of precursors on the inner side of the substrate. The precursors herein are precursors from the reactant feed requiring a longer residence time to go through a relatively slow decomposition reaction before reaching the substrate, e.g., C precursor in a deposition of C-doped pyrolytic boron nitride.

Concentric Injector Feed System: In one embodiment of the invention (not shown), the feed systems 1000 and 2000 are in the form of concentric pipes forming rings around substrate 3000, and being concentric to a central axis running perpendicular to the substrate 3000. In the system, the outermost concentric injector system 1000 comprises at least one injector feed pipe for feeding the reactant(s) with a slower decomposition reaction time prior reaching the substrate 3000. The inner concentric injector system comprises a plurality of injector feed pipes 2000, for feeding the reactant(s) with a shorter residence time to pre-react or decompose.

Substrates 3000 may be placed at various levels between the concentric injector systems 1000 and 2000, depending on the number of injector rings 1000 and 2000 available, and whether the top and/or bottom surfaces are to be coated and the thickness of the coating surface. In this embodiment of a concentric feed system, the substrates may be in a static position, or may be rotated around an axis perpendicular to the substrate surface. In one embodiment, the concentric pipes forming the first injector system and a second injector system are spatially spaced far apart for the first injector system to have a diameter of 1.5 to 20 times the diameter of the second injector system. In another embodiment, the substrate to be coated is in a static position, and the concentric injector systems rotate about the substrate.

Feed Systems of the Apparatus of the Invention: In one embodiment (not shown), the feed injector system is also coupled to a cleaning source, which provides a cleaning agent that can be periodically introduced into the chamber to remove deposition by-products and films from the processing chamber hardware. In another embodiment, the input reactant is first atomized prior to entering the chamber through the injector systems 1000 and/or 2000 respectively. Atomizing can be done using techniques known in the art, including heating the reactant feed to a temperature within 50° C. of its critical temperature prior to flowing it through a hollow needle or nozzle with a restricted outlet, etc. In yet another embodiment, the starting reactant may be in solid form which then sublime to form reaction gases in the injector systems 1000 and/or 2000.

In one embodiment of the invention, injector systems 1000 and 2000 supply reactant feeds for coating the substrate on a continuously basis, i.e., same continuous feed rate. In another embodiment, the feed rates through injector systems 1000 and 2000 may vary, for the feed system to periodically supply feed to the reactor and apply a coating onto the substrate.

In one embodiment as illustrated in FIG. 5A, the injector pipes 2000A and 2000B of the feed system 2000 are placed at about the same levels as substrates 3000A and 3000B respectively. In another embodiment, the injector pipe is placed at midpoint between two substrates, for the feed reactants from both injector pipes to direct at both the top and bottom surfaces of the substrate to be coated. In yet another embodiment with a plurality of injector feed pipes and substrates, the injector pipes may be placed at varying and variable levels away from the substrates, depending on the desired thicknesses of the coatings at the tops and bottoms on the various substrates, with the distance between each feed pipe 2000 and the substrate to be coated to be in the range of 0″ to 48″. In a second embodiment, the feed pipe is positioned at a level 3 to 48″ away from the substrate to be coated. In a third embodiment, at a distance from 2 to 10″ from the substrate to be coated.

In one embodiment as illustrated, the first injector feed system 1000 is placed at a height level mid-point between the lowest and highest positioned injector feed pipes, i.e., feed pipes 2000A and 2000B in FIGS. 4-5. In another embodiment (not shown), the first injector feed system 1000 may be placed at the same level as the top injector feed pipe 2000A, away from the bottom substrate 3000B, if little or no coating from the reactant feed from the first injector system is desired on the bottom substrate.

The plurality of feedholes in each injector pipe may be positioned in a manner to point the reactant feeds at the bottom surface of a substrate placed a level above the injector feed pipe, for coating the bottom surface of the substrate. The feedholes in the same injector pipe may also be positioned for pointing the reactant feeds at the top surface of a substrate placed below the injector feed pipe, for coating the top surface of the substrate as well. For example, reactant feeds from injector pipe 2000B can be directed to coat the bottom surface of substrate 3000A and/or the top surface of substrate 3000B. In another embodiment, reactant feeds from injector pipe 2000A can be directed to only coat the top surface of substrate 3000A.

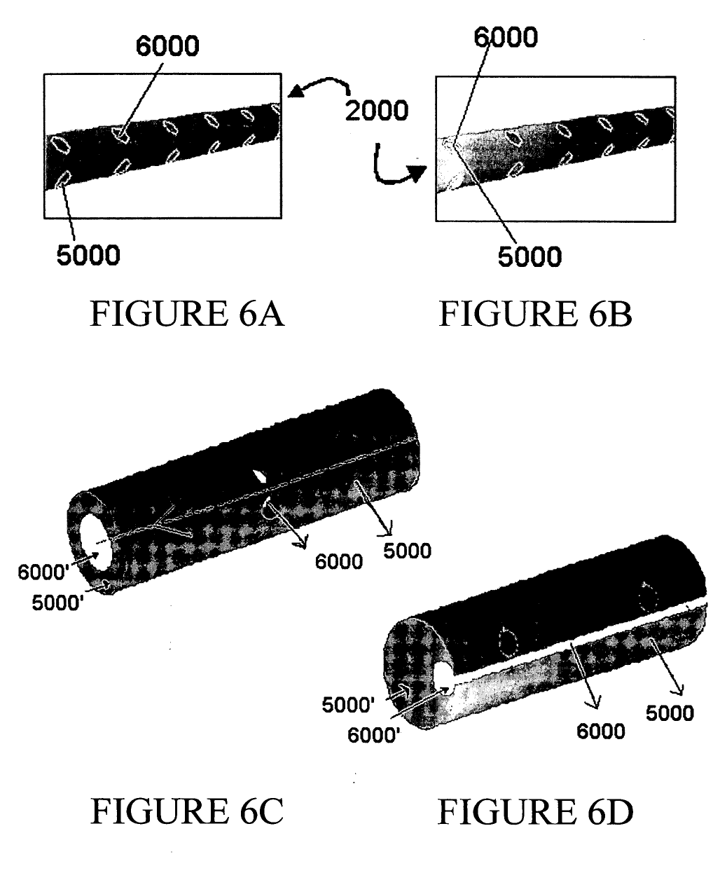

In one embodiment as illustrated in FIGS. 6A and 6B, injector pipe 2000A points the gases on both the top and bottom sides of the substrate 3000A. In another embodiment, the distribution holes on the injector pipes may be configured to for the holes to inject gases towards either one side of the substrate, the top or bottom only.

The plurality of injector pipes in the feed system 1000 and 2000 can be of the same or different sizes. In one embodiment, the injector pipes have diameters ranging from 0.10″ to 5″ and with the length bearing reactant feed openings running from 0.25 to 2 times the diameter of the substrate to be coated. In a second embodiment, the injector pipes have diameters ranging from 0.25 to 3″. In a third embodiment, from 0.50″ to 2″. In one embodiment, the length of injector pipe bearing reactant feed openings range from 0.5 to 1.5 times the diameter of the substrate to be coated.

In yet another embodiment (not shown) wherein the injector pipes are in the form of a concentric ring, the length of the injector pipes bearing reactant feed openings vary according to the distance between the injector feed pipes 1000/2000 and the substrate 3000. In one embodiment, injector pipes 2000 are in the form of concentric rings being at the top or bottom of the substrates, with the circular injector pipe 2000 having diameters ranging from 0.50 to 2 times the diameter of the substrate to be coated, and the outer circular injector pipe 1000 having a diameter of 1.25 to 20 times the diameter of the inner injector pipe 2000.

As illustrated in FIGS. 6A-6B, the injector feed system comprises a plurality of injector feed pipes, each having a plurality of openings or distribution holes for injecting reactant feeds through feed holes directed at the substrates to be coated. In one embodiment, the holes may be tampered, bored, beveled, or machined through the pipes and of sufficient size as not to restrict the flow of the reactants and/or volatile reaction intermediates onto the substrate. In one embodiment, the hole sizes range from about 0.05″-0.5″ in diameter. In one embodiment, the hole is of a uniform diameter from the inlet to outlet side. In yet another embodiment, the holes are of a flared pattern (truncated cone shape) with the hole diameter increasing from the inlet size to the outlet size, depending on the location of the perforated hole for a uniform deposition rate on the substrate located below or above the injector pipe.

In one embodiment, the hole is flared at about 22 to at least about 35 degrees. In one embodiment, the outlet side of the distribution hole is flush with the injector pipe outer surface. In another embodiment (not shown), the distribution has the shape of a nozzle having a narrow tip protruding into the chamber. In yet another embodiment, the nozzle tip of the distribution hole can be tilted or moved for pointing the reactant feed into specific locations on a substrate surface. In a fourth embodiment, the tip of the distribution hole is stationary, but is optimized for high and uniform deposition rates on the substrate surface. For example, very large angles of the distribution tip may result in good mixing and conversion to volatile reaction intermediates. However, they may also result in unwanted high deposition rates in areas other than the substrate surface. Very small angles on the other hand, can adversely affect the efficiency of jet-mixing resulting in poor conversion of the reactants to volatile reaction intermediates.

In one embodiment as illustrated in FIGS. 6A-6C, the holes are evenly distributed on ½ side of the injector pipe facing the substrates to be coated as two separate rows, with the rows being from 0.10″ to 3″ apart (from center to center), and with the holes of the same rows being from 0.25 to 6″ apart. In one embodiment, the rows are from 0.25″ to 2″ apart and the holes are from 0.5″ to 3″ apart.

The positioning of the distribution hole on the injector pipe is dependent on a number of factors, including the distance from the injector pipe to the substrate to be coated, the size of the holes, the number of distribution holes, the number of distribution rows, etc. In one embodiment wherein the reactant feeds are distributed via a plurality of holes, the holes are located at an angle of about −75 degrees to +75 degrees from a surface parallel to the substrate surface to be coated (from the center of the hole to the surface). In a second embodiment, the holes are located at an angle of about −20 to +20 degrees from a surface parallel to the surface to be coated, as illustrated in FIGS. 6C and 6D.

In yet another embodiment as illustrated in FIG. 6D, the distribution of the feed reactants is via a slit in the injector pipe for the length of the surface to be coated (the diameter of the substrate, if a circular surface). In one embodiment, the split has a width of 0.05″ to 1″. In a second embodiment, a width of 0.1″ to 0.5″ The slit can be continuous as illustrated, or it can be intermittent with a plurality of splits each being about 1″ to 4″ apart.

In one embodiment as illustrated in FIG. 6B, reactant feeds are combined prior to the inlet of the injector pipe 2000, for all reactants to distributed out of the same distribution holes. In another embodiment as illustrated in FIG. 6B, the injector pipe 2000 comprises a plurality of feed tubes, for the distribution of the reactants to be staggered with different reactant feeds exiting out of different distribution holes on the injector pipe. In yet another embodiment as illustrated in FIG. 6C, the injector pipe comprises two parallel concentric injector pipes, one inside and one outside for two different reactant feeds. In a fourth embodiment as illustrated in FIG. 6D, the injector pipe comprises two parallel pipes, with an off-center feed pipe for feeding a reactant feed via slit 6000 along the side of the injector pipe, and the second feed pipe for feeding a second reactant feed via the plurality of holes 5000 on the side of the injector pipe.

In one embodiment (not shown), the secondary injection pipe 2000 is pulled away from the substrate 3000 to avoid the high temperature region i.e. to be either flush with the apparatus surface 11 or outside the apparatus 11 being connected to it by a diffuser region. In another embodiment, the injection pipe outside 11 is replaced by multiple gas injectors spread along the length of the substrate in one row or multiple rows.

In one embodiment, the throughput through all the distribution holes (or slits) in each injector pipe, for each reactant feed, ranges from 0.1 to 50 slm (standard liters per minute). In another embodiment, 0.5 to 30 slm. In a third embodiment, from 1 to 25 slm. The flow rate can be controlled by varying the operating parameters including the diameters of the reactant distributing holes, the pump pressure, the temperatures and concentrations of the starting reactants, etc.

Exhaust Outlet: In one embodiment of an apparatus having a feed system as illustrated in FIG. 4, the chamber 11 is also be provided with at least one exhaust gap or outlet at approximately in the center of the chamber height and positioned at the side of the substrate 3000 across from the injection pipe 2000 so as to draw the feed reactants across the substrate to be coated. In another embodiment wherein the injectors are located towards the top of the chamber height, at least one exhaust gap is provided at the bottom of the chamber so as to draw the reactant feeds towards the substrate(s) to be coated.

Other Features of the Chamber of the Invention. The wall of the chamber 11 is typically fabricated from aluminum, stainless steel, or other materials suitable for high temperature corrosive environments. Inside the chamber wall, the vessel may be provided with resistive heating elements and thermal insulation as outer layers. In one embodiment (not shown), the chamber 11 comprises a water-cooled metal vacuum vessel with a water-cooled outer chamber wall, although other means for cooling can also be used. In another embodiment (not shown), resistive elements and insulation layers are also provided at the top and bottom of the chamber to further control the heat supply to the chamber. Resistive heating elements coupled to a power supply (not shown) to controllably heat the chamber 11. Electrical feedthroughs may be provided to house the electrical contact between the power supply and the resistive heater elements in the vessel, allowing the resistive heating elements to heat the inner chamber wall, including the substrate, to an elevated high temperature of at least 700° C., depending on the deposition processing parameters and the applications of the materials being deposited, e.g., a pBN crucible or a coating a heater substrate. In one embodiment, the heater maintains the substrate 3000 temperature to at least about 1000° C.

In one embodiment (not shown), a “muffle” cylinder is disposed next to heating elements defining a heated inner chamber wall, enclosing the entire system including the injector systems. In another embodiment, a partial cylinder is provided for enclosing a lower half of the CVD apparatus, i.e., the substrate deposition zone. The cylinder may be made out of graphite or sapphire for low temperature as well as high temperature applications, including high temperature CVD applications of >1400° C.

In another embodiment of the apparatus of the invention (not illustrated here), the chamber 11 comprises an inductive heating system with inductive power is coupled from an induction coil to the substrate support assembly, and the inner wall for heating the chamber as well as the substrate(s). In another embodiment of the invention (not illustrated here), inductive heating may be used in conjunction with a resistive heating system.

In one embodiment, the substrate 5 is supported by a support assembly having a built-in heater, with the support assembly being connected to the sidewall of the vacuum vessel by fastening means known in the art. In another embodiment (not shown), the vacuum vessel further comprises a resistive heater disposed within and conforming to the shape of the vacuum vessel, for heating the vacuum vessel and the substrate to the CVD temperature of at least 700° C. In yet another embodiment, an insulation layer (not shown) is further provided surrounding the resistive heater.

In one embodiment (not shown), undeposited products and remaining gases are exhausted through at least one exhaust gap in the chamber 11. The exhausting gases are transported to a mechanical feed through that is in fluid communication with an exhaust line, leading to a pumping system comprising valves and pumps that maintains a predetermined pressure in the exhaust line for continuously directing undeposited products and remaining gases from the chamber.

The chamber 11 of the invention (and the cylinder or vessel disposed within) can be of a cylinder shape, or any other geometries including that of a spherical shape. Furthermore, the injector(s) maybe located at various locations in the chamber with the injector feed system being in a horizontal position as illustrated in FIGS. 4 and 5, or they can be in a vertical position for coating vertically placed substrates. Some or all the injector feed pipes can be placed at an angle for coating substrates being positioned at an angle, or to provide desired coating patterns onto a substrate surface. Additionally, the gas exhaust ports may be located along the vacuum vessel for multiple gas exhaust zones and at different height levels approximately close to the height level of the substrates and the corresponding injector feed pipes.

### EXAMPLES

Examples are provided herein to illustrate the invention but are not intended to limit the scope of the invention.

### Example 1

In an illustrative example of a process to deposit layers in various configurations of the CVD apparatus of the invention, the heated inner walls of the chamber 11 is first heated to 1800° C. The pressure in the exhaust line is controlled to a pressure in the 300 to 450 m Torr range. Gaseous feed CH₄ and N₂ are supplied at 5 slm and 2 slm respectively through the first injector 1000. BCl₃, NH₃ and N₂ are supplied at 2 slm, 5.5 slm and 3 slm respectively through a set of two secondary injectors 2000. The feeds are mixed prior to enter the inlet of the injector pipes.

The injector are graphite pipes having a length of 63 cm, a diameter of 1″, with a plurality of feed holes each 1 cm in diameter, and placed apart at 2″ on 2000 and 1″ on 1000. The leading edge of substrate 3000 having a 450 mm diameter is located at a distance of 2″ from the secondary injectors. The first injector is spaced at further away from the secondary injectors 2000, providing enough residence time for CH₄ to decompose. In this example C deposition is directed mainly on the inner sides of the substrate (the side facing the other substrate). Divider plates 7000 help in maximizing the C precursor flow between the substrates and thus maximizing the C deposition on the inner side of the substrate. The distance between the two substrates is 120 mm.

Computational Fluid Dynamics (CFD) calculations are also carried out for this example. The apparatus inner surfaces and the substrates are assumed to be at the operating temperature (=1800° C.). The radiation will have a strong effect in minimizing any temperature differences between the solid surfaces at this high operating temperature. The gaseous reactants are assumed to enter the apparatus at room temperature. Kinetic theory is used for the calculation of the gaseous properties. A two-step reaction mechanism for PBN deposition and three-step mechanism for the C deposition is considered.

In case 1, the first injector 1000 is placed at a lead distance of 250 mm away from the leading edge of the substrates. Substrates 3000A and 3000B are placed 120 mm apart. No sacrificial plate is provided for substrate 3000. In case 2, the first injector system 1000 is placed at 500 mm away from the edge of the substrates. Substrates 3000A and 3000B are placed 120 mm apart, and a trailing sacrificial plate is provided as illustrated in FIG. 5A. In case 3, the first injector system 1000 is placed further away at 750 mm and the two substrates are placed apart at 200 mm.

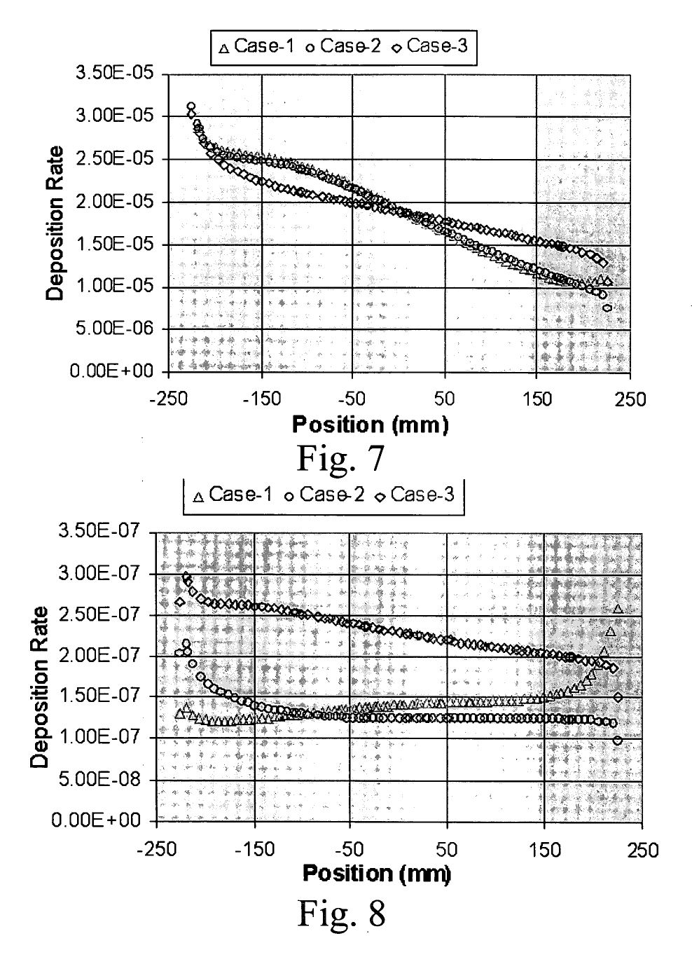

The effects of three factors, i.e., lead distance, substrate distance, and sacrificial plate, on the deposition profile of the PBN and C on the substrate were investigated. Only slight variation is noticed in the PBN deposition profiles in these cases. FIG. 7 is a graph illustrating the pBN deposition rate on mid-line of the substrate along the flow direction, with the y-axis being the surface deposition rate of pBN in kg/m²-sec, and the x-axis is the distance along the mid-line of the substrate to be coated. FIG. 7 also shows a decreasing profile of pBN, resulting in a uniform thickness as the substrate is rotated.

With respect to the deposition of carbon, the three factors being considered here have significant effect on the C deposition with the concentration of the C precursor increasing from Case-1 to Case-3. As the first injector is pulled away from the substrate, CH₄ has more residence time to convert to the C precursor. This results in higher C deposition on the leading edge of the substrate as illustrated in FIG. 8, which illustrate the carbon deposition rate on mid-line of the substrate along the flow direction, with the y axis being the surface deposition rate of carbon C in kg/m²-sec, and the x axis is the distance along the mid-line of the substrate to be coated. Case-1 shows sharp rise in the C deposition towards the trailing edge. The presence of the sacrificial-plate 4000 in Case-2 and Case-3 minimizes the flow and concentration profile variations at the trailing edge of the substrate, hence aiding in preventing the sharp increase there. In the examples with sacrificial substrate being present, sharp increase in C deposition at the leading edge is not seen.

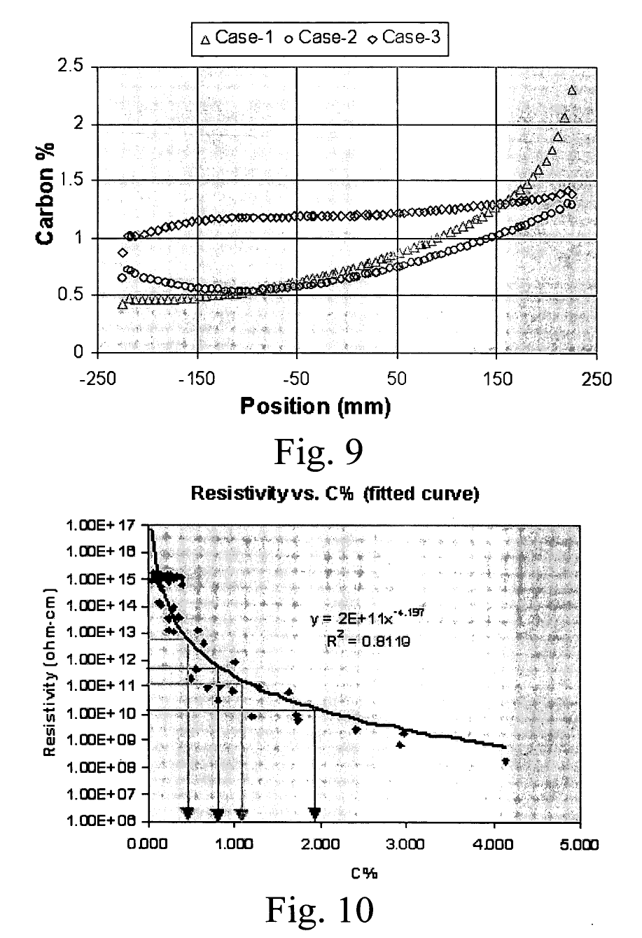

FIG. 9 is a graph showing the carbon concentration along mid-line of the substrate, with the y-axis being the concentration of C in %, and the x-axis is the distance along the mid-line of the substrate to be coated. As illustrated in FIGS. 7 and 8, the resultant depleting C deposition profile closely imitates the PBN deposition profile, giving a desirable uniform C concentration in the deposited coating on the substrate (with little variations along the mid-line of the substrate as compared to the profiles of cases C-2 and C-1). As shown in FIG. 10, the C percentage in the film affects its resistivity. Hence, the C percentage and the thickness of the film decide the resistance characteristics of the film. The design parameters considered here can be effectively used to achieve uniformity of the film thickness and resistance.

### Example 2

In this example, the sensitivity of the resistance characteristics of the film is studied with the flow rates of the C dopant (as CH₄ feed) in injector system 1000 varying from 3 slm to 7 slm. It is found that increasing the CH₄ flow rate increases the C precursor concentration near the substrate, which in turn, increasing the C % in the film and hence the average resistance of the film decreases with the concentration. Also, it is found that the resistance ratio (max./min) increases with the flow rates. Therefore, the dopant CH4 flow rate—as fed through the injector system 1000 being placed further away from the substrate, is an effective design parameter which gives a good control on the C deposition on the substrate, and subsequently, the resistance characteristics of the coated film.

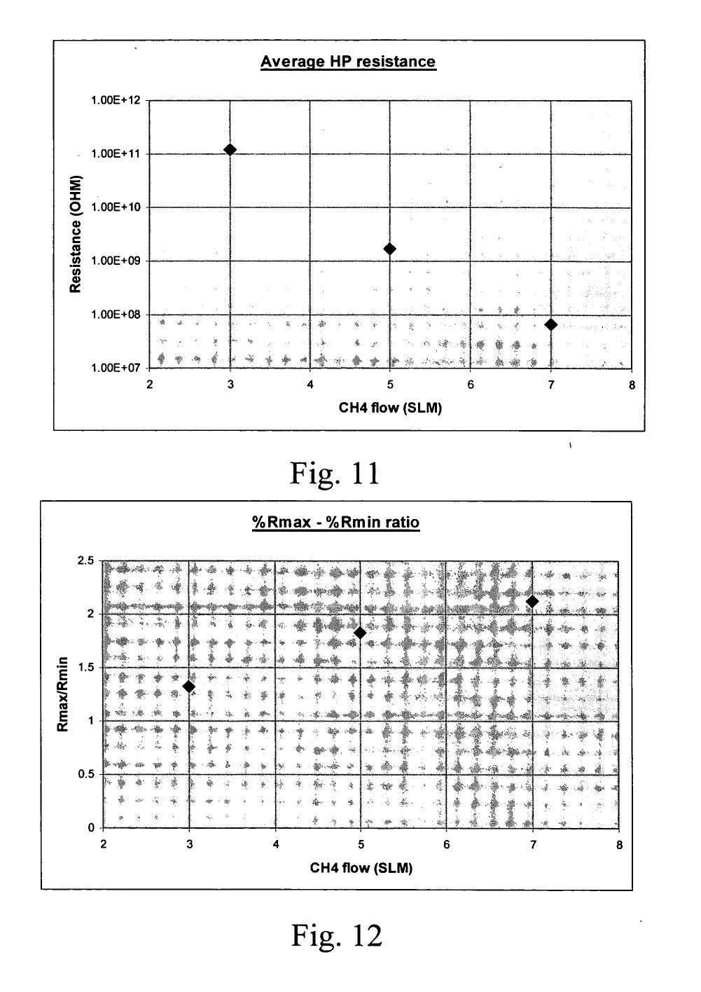

FIG. 11 illustrates the sensitivity of resistance of the CPBN film on the substrate to the flow rate of CH4 from the first injector system. FIG. 12 is a graph illustrating the resistance non-uniformity variation with the CH4 flow rate, measured as ratio of maximum to minimum resistance on the substrate.

### Example 3

In another illustrative example, a detailed set of design of experiments (DOE) was carried out with the two design factors in Example 1. In this example, a CPBN film on the substrate is desired, which has resistance characteristics as described in FIG. 11. The C percentage in the film is related to the resistivity as in FIG. 10. This resistivity and the film thickness can be used to estimate the resistance of the film on the substrate. These calculations are summarized as in FIG. 12. A parametric analysis is carried out to study the effect of two parameters of the apparatus—the distance between the substrates and lead distance of the first injector from the substrate—on the resistance characteristics of the deposited film. These two parameters have strong influence on the resistance of the deposited film as seen from the minimum and maximum resistances on the substrate.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. All citations referred herein are incorporated by reference.

1. A chemical vapor deposition (CVD) system comprising:
a reaction chamber maintained at a pressure of less than 100 torr, in which at least a substrate to be coated is disposed within;
heating means for maintaining the substrate at a temperature of at least 700° C.;
at least one exhaust outlet in fluid communication with the reaction chamber;
a feed system comprising a plurality of injector systems for supplying a plurality of reactant gases or gas mixtures to the reaction chamber;
wherein the plurality of injector systems are spatially spaced sufficiently far apart for differential pre-reaction of the plurality of reactant gases or gas mixtures, forming a coating deposit that is substantially uniform in thickness and chemical composition on the substrate.

2. The CVD system of claim 1, wherein the plurality of injector systems comprise a first injector system and a second injector system, and where the first injection system is spatially spaced sufficiently far apart from the second injector system for at least one of the reactant gases or gas mixtures supplied via the first injector system to be pre-treated prior to reacting with the reactant gases or gas mixtures supplied by the second injector system.

3. The CVD system of claim 1, wherein the reactant gases or gas mixtures supplied via the first injector system is pre-treated by an energy source selected from plasma treatment, UV treatment, microwave treatment, thermal treatment, and combinations thereof.

4. The CVD system of claim 1, further comprising at least a sacrificial substrate positioned adjacent to the at least one substrate to be coated.

5. The CVD system of claim 4, wherein the sacrificial substrate is adjacent to and surrounds the at least one substrate to be coated.

6. The CVD system of claim 1, further comprising rotating means for rotating the at least one substrate while it is being coated.

7. The CVD system of claim 1, wherein the plurality of injector systems comprise a first injector system and a second injector system, and wherein the first injector system is placed at a length between 1.5 to 20 times the length between the second injector system and the substrate to be coated.

10. The CVD system of claim 7, wherein a horizontal distance between the second injector system and the substrate to be coated is in the range of 0″ to 48″.

11. The CVD system of claim 10, wherein a horizontal distance between the second injector system and the substrate to be coated is in the range of 2″ to 10″.

12. The CVD system of claim 7, wherein the plurality of injector systems comprise a first injector system and a second injector system, and wherein the first injector system is placed at a length between 3 to 18 times the length between the second injector system and the substrate to be coated.

13. The CVD system of claim 12, wherein the plurality of injector systems comprise a first injector system and a second injector system, and wherein the first injector system is placed at a length between 5 to 10 times the length between the second injector system and the substrate to be coated.

14. The CVD system of claim 1, wherein the plurality of injector systems comprise a first injector system and a second injector system, and wherein the first and second injector systems comprise concentric pipes disposed above the substrate to be coated.

15. The CVD system of claim 14, wherein the first injector system and a second injector system are spatially spaced fir apart for the first injector system to have a diameter of 1.5 to 20 times the diameter of the second injector system.

16. The CVD system of claim 14, wherein the substrate to be coated is fixed and the plurality of injector systems comprising concentric pipes rotate about the substrate to be coated.

17. The CVD system of claim 14, wherein each of the concentric pipe is for feeding a different reactant gas or gas mixture to the reaction chamber.

18. The CVD system of claim 14, wherein the plurality of concentric pipes comprise at least one innermost concentric pipe and one outermost concentric pipe and wherein the innermost concentric pipe is for feeding a first reactant with a shorter residence time and the outermost concentric pipe is for feeding a second reactant having a longer residence time than the first reactant.

19. The CVD system of claim 1, wherein the plurality of injectors are spatially spaced sufficiently far apart for the coating layer on the substrate to have a coating thickness variation of less than 10%, expressed as a ratio of standard deviation to average.

20. The CVD system of claim 1, wherein the plurality of injectors are spatially spaced Is sufficiently far apart for the coating layer on the substrate to have a coating concentration variation of less than 10%, expressed as a ratio of standard deviation to average of the concentration of elements contained in the coating.

21. The CVD system of claim 19, wherein the plurality of injectors are spatially spaced sufficiently far apart for the coating layer on the substrate to have a coating thickness variation of less than 5%, as expressed as a ratio of standard deviation to average.

22. The CVD system of claim 19, wherein the plurality of injectors are spatially spaced sufficiently far apart for the coating layer on the substrate to have a coating concentration variation of less than 5%, expressed as a ratio of standard deviation to average of the concentration of elements contained in the coating.

23. The CVD system of claim 1, wherein the at least one exhaust outlet is located at a location in the chamber opposite from the feed system as to draw the plurality of reactant gases or gas mixtures over the substrate to be coated.

24. The CVD system of claim 1, wherein the plurality of injector systems comprise a first injector system and a second injector system for feeding a plurality of reactant gases or gas mixtures to the reaction chamber, and wherein the plurality of reactant gases or gas mixtures comprise a feed of BCl₃ and a feed of NH₃.

25. The CVD system of claim 24, wherein the plurality of reactant gases or gas mixtures further comprise a feed of CH₄.

26. The CVD system of claim 25, or the deposition of a coating layer of carbon doped pyrolytic boron nitride on the substrate.

27. The CVD system of claim 1, wherein the plurality of injector systems are spatially spaced sufficiently far apart for differential pre-reaction of the plurality of reactant gases or gas mixtures, and wherein a horizontal distance between the injector systems is variable.

28. The CVD system of claim 27, wherein the plurality of injector systems comprise a first injector system and a second injector system, wherein the first injector is spatially spaced farther apart from the substrate than the second injector, and wherein a horizontal distance between the substrate and the first injector system is variable.

29. The CVD system of claim 27, wherein the plurality of injector systems comprise a first injector system and a second injector system, wherein the first injector is spatially spaced farther apart from the substrate than the second injector, and wherein a horizontal distance between the substrate and the second injector system is variable.

30. The CVD system of claim 1, wherein at least one of the injector systems comprises a plurality of substantially concentric pipes positioned therein, each one of the plurality of substantially concentric pipes for providing at least one reactant gas or gas mixture into the reaction chamber.

31. The CVD system of claim 1, wherein the feed system comprises a plurality of injector pipes, wherein at least one of the injector pipes has a plurality of holes formed in a portion of the pipe, for feeding reactant gas or gas mixtures to the reaction chamber, wherein each hole has a diameter ranging from about 0.05″-0.5″.

32. The CVD system of claim 31, wherein the plurality of the holes are distributed on at least ½ of the injector pipes facing the substrate to be coated.

33. The CVD system of claim 31, wherein the plurality of the holes are distributed forming at least two separate rows, and wherein the rows are from 0.10″ to 3″ apart.

34. The CVD system of claim 31, wherein the at least one of injector pipes has a sufficient number of holes having a sufficient hole size for supplying at least a reactant gas or gas mixture to the reaction chamber at a rate of 0.1 to 50 slm.

35. The CVD system of claim 1, wherein at least one of the injector systems comprises a plurality of injector pipes and wherein at least one injector pipe comprises a slit for supplying at least a reactant gas or gas mixture to the reaction chamber at a rate of 0.1 to 50 slm.

36. The CVD system of claim 1, further comprising at least a divider plate positioned at about a same horizontal level as the at least one substrate to be coated, for channeling the reacted precursor towards the substrate to be coated.

37. A chemical vapor deposition (CVD) process for coating a substrate with a layer having a thickness variation of less than 10% and comprising a dopant, the process comprising:
placing the substrate to be coated in a vacuum reaction chamber maintained at less than 100 torr,
heating the substrate to a temperature of at least 700° C.,
providing a feed system comprising a first injector system and a second injector system for providing a plurality of reactant feeds into the reactor including a dopant component;
wherein the first injector system is spatially spaced sufficiently further apart from the substrate than the second injector system to provide the dopant component feed a different residence time before reaching the substrate.

38. The CVD process of claim 37, wherein the substrate coating comprises at least one of an oxide, nitride, oxynitride of elements selected from a group consisting of Al, B, Si, Ga, refractory hard metals, transition metals, and combinations thereof.

39. The CVD process of claim 37, wherein the dopant component comprises at least one of silicon, carbon, and oxygen.

40. The CVD process of claim 39, wherein the dopant component contains CH₄.
